(19) United States
(12) Patent Application Publication
(10) Pub. No.: US 2025/0253217 A1
(43) Pub. Date: Aug. 7, 2025

(54) PACKAGE COMPRISING SUBSTRATES WITH POST INTERCONNECTS

(71) Applicant: QUALCOMM Incorporated, San Diego, CA (US)

(72) Inventors: Joan Rey Villarba BUOT, Escondido, CA (US); Zhijie WANG, San Diego, CA (US); Hong Bok WE, San Diego, CA (US); Sang-Jae LEE, San Diego, CA (US)

(21) Appl. No.: 18/430,395

(22) Filed: Feb. 1, 2024

(51) Int. Cl. H01L 23/498; H01L 23/00; H01L 23/31; H01L 23/538; H01L 25/10

(52) U.S. Cl. CPC H01L 23/49811; H01L 23/3128; H01L 23/5383; H01L 24/16; H01L 24/50; H01L 25/105; H01L 24/32; H01L 24/73; H01L 2224/16227; H01L 2224/32225; H01L 2224/73204

(57) ABSTRACT

A package comprising a first substrate, a first integrated device coupled to the first substrate, a second substrate coupled to the first substrate through at least a plurality of solder interconnects, and an encapsulation layer located between the first substrate and the second substrate. The first substrate comprises at least one first dielectric layer; and a first plurality of interconnects, wherein the first plurality of interconnects include a first plurality of post interconnects. The second substrate comprises at least one second dielectric layer; and a second plurality of interconnects, wherein the second plurality of interconnects include a second plurality of post interconnects.

### FIELD

Various features relate to packages with substrates and integrated devices.

### BACKGROUND

A package may include a substrate and integrated devices. These components are coupled together to provide a package that may perform various electrical functions. There is an ongoing need to provide better performing packages. Moreover, there is also an ongoing need to reduce the overall size of the packages.

### SUMMARY

Various features relate to packages with substrates and integrated devices.

One example provides a package comprising a first substrate, a first integrated device coupled to the first substrate, a second substrate coupled to the first substrate through at least a plurality of solder interconnects, and an encapsulation layer located between the first substrate and the second substrate. The first substrate comprises at least one first dielectric layer; and a first plurality of interconnects, wherein the first plurality of interconnects include a first plurality of post interconnects. The second substrate comprises at least one second dielectric layer; and a second plurality of interconnects, wherein the second plurality of interconnects include a second plurality of post interconnects.

Another example provides a method for fabricating a package. The method provides a first substrate comprising at least one first dielectric layer; and a first plurality of interconnects, wherein the first plurality of interconnects include a first plurality of post interconnects. The method couples a first integrated device to the first substrate. The method couples a second substrate to the first substrate through at least a plurality of solder interconnects. The second substrate comprises at least one second dielectric layer; and a second plurality of interconnects, wherein the second plurality of interconnects include a second plurality of post interconnects. The method forms an encapsulation layer located between the first substrate and the second substrate.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates an exemplary cross sectional profile view of a package that includes substrates comprising post interconnects.

FIG. 2 illustrates an exemplary cross sectional profile view of a package that includes substrates comprising post interconnects.

FIG. 3 illustrates an exemplary cross sectional profile view of a package that includes substrates comprising post interconnects.

FIG. 4 illustrates an exemplary cross sectional profile view of a package that includes substrates comprising post interconnects.

FIG. 5 illustrates an exemplary cross sectional profile view of an integrated device.

FIGS. 6A-6C illustrate an exemplary sequence for fabricating a package that includes substrates comprising post interconnects.

FIG. 7 illustrates an exemplary flow chart of a method for fabricating a package that includes substrates comprising post interconnects.

FIG. 8 illustrates an exemplary flow chart of a method for fabricating a package that includes substrates coupled through solder interconnects.

FIGS. 9A-9C illustrate an exemplary sequence for fabricating a substrate that includes post interconnects.

FIGS. 10A-10B illustrate an exemplary sequence for fabricating a substrate that includes post interconnects.

FIG. 11 illustrates an exemplary flow chart of a method for fabricating a substrate that includes post interconnects.

FIG. 12 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

The present disclosure describes a package that comprises a first substrate, a first integrated device coupled to the first substrate, a second substrate coupled to the first substrate through at least a plurality of solder interconnects, and an encapsulation layer located between the first substrate and the second substrate. The first substrate comprises at least one first dielectric layer; and a first plurality of interconnects, wherein the first plurality of interconnects include a first plurality of post interconnects. The second substrate comprises at least one second dielectric layer; and a second plurality of interconnects, wherein the second plurality of interconnects include a second plurality of post interconnects. As will be further described below, the package provides improved, efficient and/or effective heat dissipation for the first integrated device. In particular, the use of post interconnects in substrates may help improve the overall thermal performance of the package, which can lead to improved performance of the package.

Exemplary Package Comprising Substrates with Post Interconnects

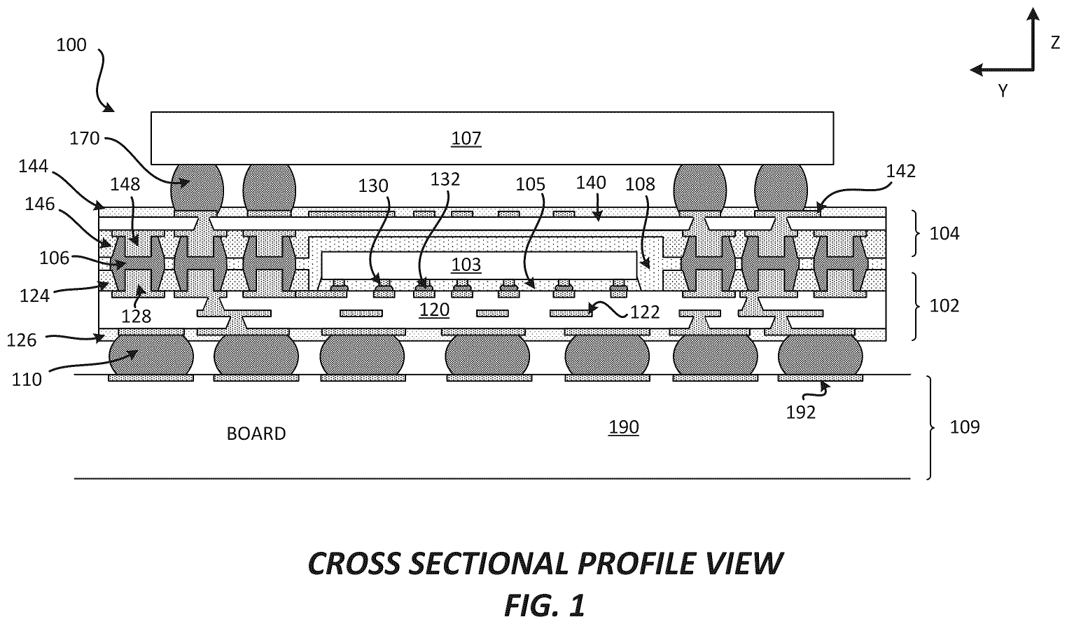

FIG. 1 illustrates a cross sectional profile view of a package 100 that includes substrates with post interconnects. The package 100 may be a package on package (PoP). The package 100 is coupled to a board 109 through a plurality of solder interconnects 110. The board 109 includes at least one board dielectric layer 190 and a plurality of board interconnects 192. The board 109 may include a printed circuit board (PCB).

The package 100 includes a substrate 102, a substrate 104, an integrated device 103, an integrated device 107 and an encapsulation layer 108. The substrate 102 may be a first substrate (e.g., bottom substrate). The substrate 102 includes at least one dielectric layer 120, a plurality of interconnects 122, a solder resist layer 124 and a solder resist layer 126. The at least one dielectric layer 120 may include at least one first dielectric layer. The plurality of interconnects 122 may include a plurality of post interconnects 128. The plurality of interconnects 122 may include a first plurality of interconnects. The plurality of post interconnects 128 may include a first plurality of post interconnects. The substrate 102 may be a laminated substrate.

The substrate 104 may be a second substrate (e.g., top substrate). The substrate 104 includes at least one dielectric layer 140, a plurality of interconnects 142, a solder resist layer 144 and a solder resist layer 146. The at least one dielectric layer 140 may include at least one second dielectric layer. The plurality of interconnects 142 may include a plurality of post interconnects 148. The plurality of interconnects 142 may include a second plurality of interconnects. The plurality of post interconnects 148 may include a second plurality of post interconnects. The substrate 104 may be a laminated substrate. The substrate 104 may be an interposer.

The integrated device 103 may be a first integrated device. The integrated device 103 may be coupled to the substrate 102 through a plurality of pillar interconnects 130 and a plurality of solder interconnects 132. The integrated device 103 may be coupled to the interconnects from the plurality of interconnects 122 through the plurality of pillar interconnects 130 and the plurality of solder interconnects 132. The plurality of solder interconnects 132 are touching interconnects from the plurality of interconnects 122. An underfill 105 is located between the integrated device 103 and the substrate 102. The underfill 105 may touch the integrated device 103, the substrate 102, the plurality of pillar interconnects 130 and/or the plurality of solder interconnects 132.

The substrate 104 is coupled to the substrate 102 through a plurality of solder interconnects 106. The plurality of solder interconnects 106 are located between the substrate 102 and the substrate 104. The plurality of solder interconnects 106 are coupled to the plurality of post interconnects 128 and the plurality of post interconnects 148. The plurality of solder interconnects 106 may be located in cavities of the solder resist layer 124 of the substrate 102. The plurality of solder interconnects 106 may be located in cavities of the solder resist layer 144 of the substrate 104. In some implementations, the plurality of post interconnects 128 may touch the plurality of post interconnects 148. The plurality of post interconnects 128 may or may not touch the plurality of post interconnects 148. In some implementations, solder interconnect(s) may be located between the plurality of post interconnects 128 and the plurality of post interconnects 148.

The encapsulation layer 108 is coupled to the substrate 102 and the substrate 104. The encapsulation layer 108 is located between the substrate 102 and the substrate 104. The encapsulation layer 108 may touch the substrate 102, the substrate 104, the integrated device 103 and/or the plurality of solder interconnects 106. For example, the encapsulation layer 108 may touch the back side of the integrated device 103 and/or the side surface of the integrated device 103. Portions of the encapsulation layer 108 may be located between the substrate 104 and the integrated device 103. The encapsulation layer 108 may be located laterally of the integrated device 103, the plurality of post interconnects 128, the plurality of post interconnects 148 and/or the plurality of solder interconnects 106. The encapsulation layer 108 may include a mold, a resin and/or an epoxy. The encapsulation layer 108 may be a means for encapsulation. The encapsulation layer 108 may be provided by using a compression and transfer molding process, a sheet molding process, or a liquid molding process.

In some implementations, the plurality of post interconnects 128 may have a height of about 100 micrometers. In some implementations, the plurality of post interconnects 148 may have a height of about 20 micrometers. In some implementations, the plurality of post interconnects 128 may have a height of about 20 micrometers. In some implementations, the plurality of post interconnects 148 may have a height of about 100 micrometers. However, different implementations, may use post interconnects with different heights. For example, any of the post interconnects (e.g., 128, 148) may have a thickness in a range of about 15-120 micrometers. In some implementations, the use of the post interconnects may allow the integrated device 103 to be thicker by about 25-65 micrometers (e.g., die substrate of the integrated device 103 may be thicker by about 25-65 micrometers). As will be further described below, the increase in thickness of the integrated device 103 (e.g., increase thickness of the die substrate) may provide improved heat dissipation since the die substrate (which may include silicon) may have better thermal conductivity properties than the encapsulation layer 108. In some implementations, the pitch of post interconnects between the substrate 102 and the substrate 104 may be as low as 210 micrometers.

The plurality of post interconnects 128 and/or the plurality of post interconnects 148 may be thicker than interconnects (e.g., surface interconnects, surface pad interconnects, surface trace interconnects) from the plurality of interconnects 122 and/or from the plurality of interconnects 142. The use of the plurality of post interconnects 128 and/or the plurality of post interconnects 148 may help provide and/or accommodate an integrated device (e.g., 103) that is thicker (e.g., has thicker silicon substrate). Generally speaking, silicon has better thermal conductivity properties than the encapsulation layer 108. Thus, a thicker silicon substrate for the integrated device 103 provides better and/or improved thermal performance (e.g., better and/or improved heat dissipation) for the integrated device 103, which means improved thermal performance for the package. Without some of the post interconnects, the thickness of the integrated device 103 would have to be reduced and/or thinned, which reduces the heat dissipation performance of the integrated device 103 and the package 100.

The integrated device 107 may be a second integrated device. The integrated device 107 may be coupled to the substrate 104 through a plurality of solder interconnects 170. The plurality of solder interconnects 170 may touch interconnects from the plurality of interconnects 142 of the substrate 104.

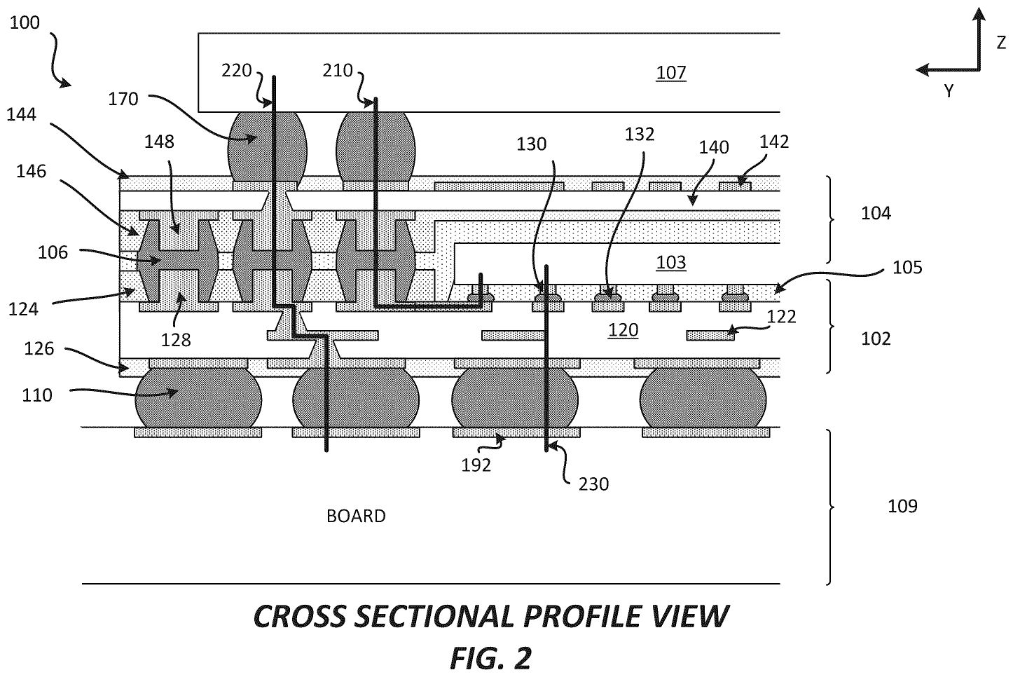

FIG. 2 illustrates a close up view of the package 100. FIG. 2 also illustrates exemplary electrical paths for the package 100. FIG. 2 illustrates an electrical path 210, an electrical path 220 and an electrical path 230.

The electrical path 210 is an example of a conceptual electrical path between the integrated device 103 and the integrated device 107. The electrical path 210 includes (i) a pillar interconnect from the plurality of pillar interconnects 130, (ii) a solder interconnect from the plurality of solder interconnects 132, (iii) at least one interconnect from the plurality of interconnects 122, (iv) a post interconnect from the plurality of post interconnects 128, (v) a solder interconnect from the plurality of solder interconnects 106, (vi) a post interconnect from the plurality of post interconnects 148, (vii) at least one interconnect from the plurality of interconnects 142, and/or (viii) a solder interconnect from the plurality of solder interconnects 170.

The electrical path 220 is an example of a conceptual electrical path between the board 109 and the integrated device 107. The electrical path 220 includes (i) a board interconnect from the plurality of board interconnects 192, (ii) a solder interconnect from the plurality of solder interconnects 110, (iii) at least one interconnect from the plurality of interconnects 122, (iv) a post interconnect from the plurality of post interconnects 128, (v) a solder interconnect from the plurality of solder interconnects 106, (vi) a post interconnect from the plurality of post interconnects 148, (vii) at least one interconnect from the plurality of interconnects 142, and/or (viii) a solder interconnect from the plurality of solder interconnects 170.

The electrical path 230 is an example of a conceptual electrical path between the board 109 and the integrated device 103. The electrical path 230 includes (i) a board interconnect from the plurality of board interconnects 192, (ii) a solder interconnect from the plurality of solder interconnects 110, (iii) at least one interconnect from the plurality of interconnects 122, (iv) a solder interconnect from the plurality of solder interconnects 132, and/or (v) a pillar interconnect from the plurality of pillar interconnects 130.

In some implementations, at least some of the solder interconnects from the plurality of solder interconnects 106 may touch the solder resist layer 124 and/or the solder resist layer 146.

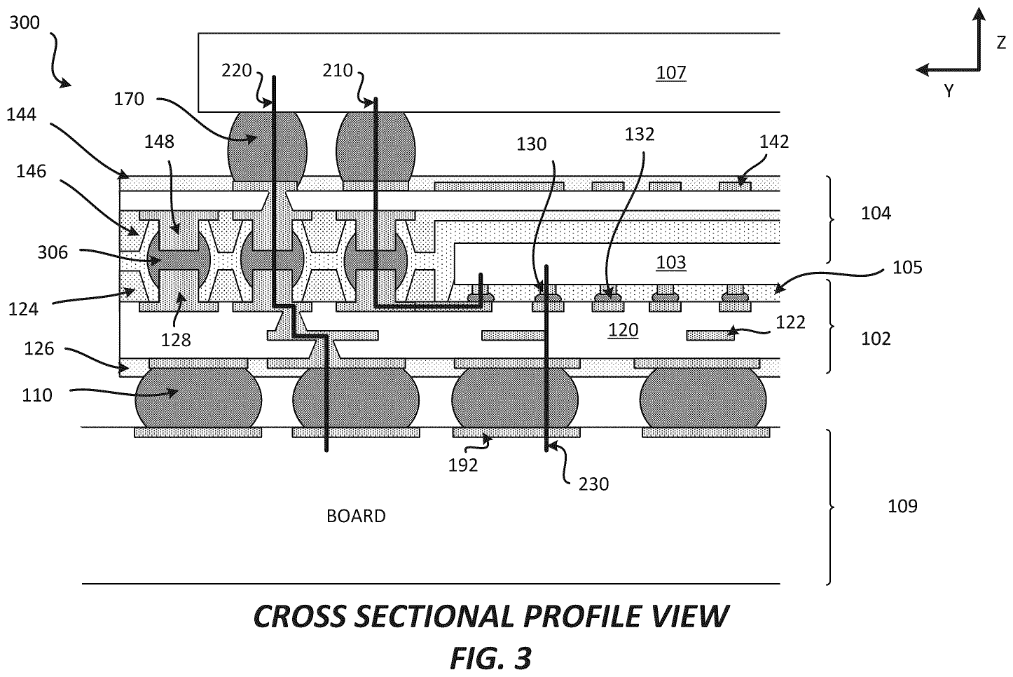

FIG. 3 illustrates a close up view of a package 300. The package 300 is similar to the package 100 and may include the same components as the package 100. Thus, the description of the package 100 in at least FIGS. 1 and 2, is also applicable to the package 300. However, the package 300 includes a plurality of solder interconnects 306.

As shown in FIG. 3, the package 300 includes a substrate 102, a substrate 104, an integrated device 103, an integrated device 107, an encapsulation layer 108 and a plurality of solder interconnects 306. The substrate 104 is coupled to the substrate 102 through a plurality of solder interconnects 306. The plurality of solder interconnects 306 are located between the substrate 102 and the substrate 104. The plurality of solder interconnects 306 are coupled to the plurality of post interconnects 128 and the plurality of post interconnects 148. The plurality of solder interconnects 306 may be located in cavities of the solder resist layer 124 of the substrate 102. The plurality of solder interconnects 306 may be located in cavities of the solder resist layer 144 of the substrate 104. In some implementations, the plurality of post interconnects 128 may touch the plurality of post interconnects 148. In some implementations, solder interconnect(s) may be located between the plurality of post interconnects 128 and the plurality of post interconnects 148. The plurality of solder interconnects 306 may be similar to the plurality of solder interconnects 106. However, the size of the plurality of solder interconnects 306 may not be as big as the plurality of solder interconnects 106. In some implementations, at least some of the solder interconnects from the plurality of solder interconnects 306 may not touch the solder resist layer 124 and/or the solder resist layer 146.

The encapsulation layer 108 is coupled to the substrate 102 and the substrate 104. The encapsulation layer 108 is located between the substrate 102 and the substrate 104. The encapsulation layer 108 may touch the substrate 102, the substrate 104, the integrated device 103, the plurality of solder interconnects 306, the plurality of post interconnects 128 and/or the plurality of post interconnects 148. For example, the encapsulation layer 108 may touch the plurality of post interconnects 128 and/or the plurality of post interconnects 148.

The electrical path 210 is an example of a conceptual electrical path between the integrated device 103 and the integrated device 107. The electrical path 210 includes (i) a pillar interconnect from the plurality of pillar interconnects 130, (ii) a solder interconnect from the plurality of solder interconnects 132, (iii) at least one interconnect from the plurality of interconnects 122, (iv) a post interconnect from the plurality of post interconnects 128, (v) a solder interconnect from the plurality of solder interconnects 306, (vi) a post interconnect from the plurality of post interconnects 148, (vii) at least one interconnect from the plurality of interconnects 142, and/or (viii) a solder interconnect from the plurality of solder interconnects 170.

The electrical path 220 is an example of a conceptual electrical path between the board 109 and the integrated device 107. The electrical path 220 includes (i) a board interconnect from the plurality of board interconnects 192, (ii) a solder interconnect from the plurality of solder interconnects 110, (iii) at least one interconnect from the plurality of interconnects 122, (iv) a post interconnect from the plurality of post interconnects 128, (v) a solder interconnect from the plurality of solder interconnects 306, (vi) a post interconnect from the plurality of post interconnects 148, (vii) at least one interconnect from the plurality of interconnects 142, and/or (viii) a solder interconnect from the plurality of solder interconnects 170.

The electrical path 230 is an example of a conceptual electrical path between the board 109 and the integrated device 103. The electrical path 230 includes (i) a board interconnect from the plurality of board interconnects 192, (ii) a solder interconnect from the plurality of solder interconnects 110, (iii) at least one interconnect from the plurality of interconnects 122, (iv) a solder interconnect from the plurality of solder interconnects 132, and/or (v) a pillar interconnect from the plurality of pillar interconnects 130.

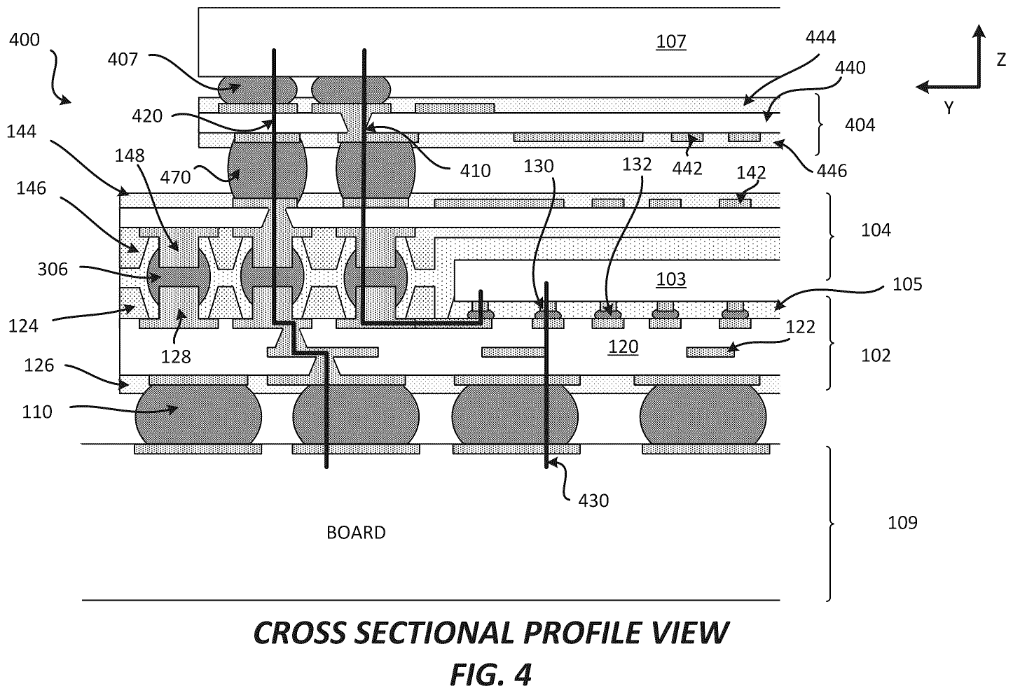

FIG. 4 illustrates a close up view of a package 400. The package 400 is similar to the package 100 and/or the package 300 and may include the same components as the package 100 and/or the package 300. Thus, the description of the package 100 and/or the package 300 in at least FIGS. 1-3, are also applicable to the package 400.

As shown in FIG. 4, the package 400 includes a substrate 102, a substrate 104, an integrated device 103, an encapsulation layer 108, a plurality of solder interconnects 306, a substrate 404 and an integrated device 107.

The substrate 404 includes at least one dielectric layer 440, a plurality of interconnects 442, a solder resist layer 444 and a solder resist layer 446. The substrate 404 is coupled to the substrate 104 through the plurality of solder interconnects 470. The plurality of solder interconnects 470 may be coupled to and touch the plurality of interconnects 142 and the plurality of interconnects 442.

FIG. 4 also illustrates examples of electrical paths for the package 400. In particular, FIG. 4 illustrates an electrical path 410, an electrical path 420 and an electrical path 430.

The electrical path 410 is an example of a conceptual electrical path between the integrated device 103 and the integrated device 107. The electrical path 210 includes (i) a pillar interconnect from the plurality of pillar interconnects 130, (ii) a solder interconnect from the plurality of solder interconnects 132, (iii) at least one interconnect from the plurality of interconnects 122, (iv) a post interconnect from the plurality of post interconnects 128, (v) a solder interconnect from the plurality of solder interconnects 306, (vi) a post interconnect from the plurality of post interconnects 148, (vii) at least one interconnect from the plurality of interconnects 142, (viii) a solder interconnect from the plurality of solder interconnects 470, (ix) at least one interconnect from the plurality of interconnects 442, and/or (x) a solder interconnect from the plurality of solder interconnects 407.

The electrical path 420 is an example of a conceptual electrical path between the board 109 and the integrated device 107. The electrical path 220 includes (i) a board interconnect from the plurality of board interconnects 192, (ii) a solder interconnect from the plurality of solder interconnects 110, (iii) at least one interconnect from the plurality of interconnects 122, (iv) a post interconnect from the plurality of post interconnects 128, (v) a solder interconnect from the plurality of solder interconnects 306, (vi) a post interconnect from the plurality of post interconnects 148, (vii) at least one interconnect from the plurality of interconnects 142, (viii) a solder interconnect from the plurality of solder interconnects 470, (ix) at least one interconnect from the plurality of interconnects 442, and/or (x) a solder interconnect from the plurality of solder interconnects 407.

The electrical path 430 is an example of a conceptual electrical path between the board 109 and the integrated device 103. The electrical path 230 includes (i) a board interconnect from the plurality of board interconnects 192, (ii) a solder interconnect from the plurality of solder interconnects 110, (iii) at least one interconnect from the plurality of interconnects 122, (iv) a solder interconnect from the plurality of solder interconnects 132, and/or (v) a pillar interconnect from the plurality of pillar interconnects 130.

### Exemplary Integrated Device

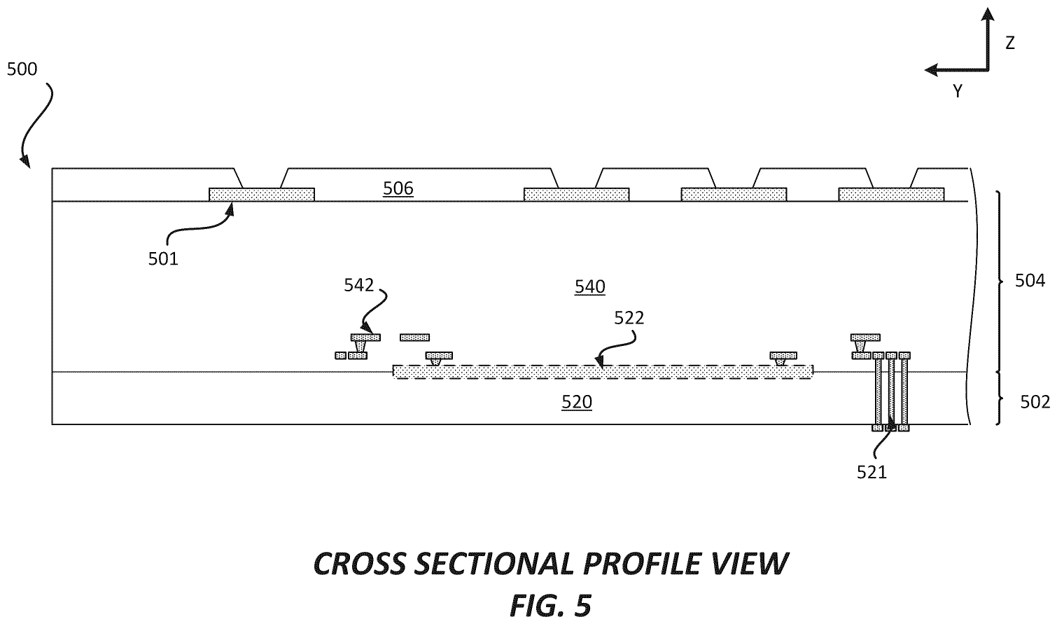

FIG. 5 illustrates a cross sectional profile view of an integrated device 500 that includes a die substrate. The integrated device 500 may represent the integrated device 103 and/or the integrated device 107. The integrated device 500 includes a die substrate portion 502 and a die interconnection portion 504. The die substrate portion 502 includes a die substrate 520, an active region 522 and a plurality of through substrate vias 521. The active region 522 may include a plurality of logic cells, a plurality of transistors, and/or a plurality of filters. Different implementations may use different types of transistors, such as a field effect transistor (FET), planar FET, finFET, and a gate all around FET. In some implementations, a front end of line (FEOL) process may be used to fabricate the active region 522 of the die substrate 520.

The die substrate 520 may include silicon (Si). The die substrate 520 may comprise a bulk silicon. The bulk silicon may include a monolith silicon. The plurality of through substrate vias 521 may extend through the die substrate 520. Different implementations may have different thicknesses for the die substrate 520.

The die interconnection portion 504 includes at least one dielectric layer 540 and a plurality of die interconnects 542. The die interconnection portion 504 is coupled to the die substrate portion 502. The plurality of die interconnects 542 are coupled to the active region 522 of the die substrate portion 502. The plurality of die interconnects 542 may be coupled to the plurality of through substrate vias 521. The die interconnection portion 504 may also include a plurality of pad interconnects 501 and a passivation layer 506. The plurality of die interconnects 542 may be coupled to the plurality of through substrate vias 521. In some implementations, a back end of line (BEOL) process may be used to fabricate the die interconnection portion 504.

In some implementations, an electrical path to and/or from an active region 522 may include at least one die interconnect from the plurality of die interconnects 542, at least one through substrate via from the plurality of through substrate vias 521. In some implementations, an electrical path to and/or from an active region 522 may include at least one die interconnect from the plurality of die interconnects 542, at least one pad interconnect from the plurality of pad interconnects 501.

An integrated device (e.g., 103, 107) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device may include at least one electronic circuit (e.g., first electronic circuit, second electronic circuit, etc. . . . ). An integrated device may include an input/output (I/O) hub. An integrated device may include transistors. An integrated device may be an example of an electrical component and/or electrical device.

In some implementations, an integrated device may be a chiplet. A chiplet may be fabricated using a process that provides better yields compared to other processes used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one more integrated devices). As mentioned above, using several chiplets that perform several functions may reduce the overall cost of a package relative to using a single chip to perform all of the functions of a package. In some implementations, one or more of the chiplets and/or one of more of integrated devices (e.g., 103) described in the disclosure may be fabricated using the same technology node or two or more different technology nodes. For example, an integrated device may be fabricated using a first technology node, and a chiplet may be fabricated using a second technology node that is not as advanced as the first technology node. In such an example, the integrated device may include components (e.g., interconnects, transistors) that have a first minimum size, and the chiplet may include components (e.g., interconnects, transistors) that have a second minimum size, where the second minimum size is greater than the first minimum size. In some implementations, a first integrated device and a second integrated device of a package, may be fabricated using the same technology node or different technology nodes. In some implementations, a chiplet and another chiplet of a package, may be fabricated using the same technology node or different technology nodes.

A technology node may refer to a specific fabrication process and/or technology that is used to fabricate an integrated device and/or a chiplet. A technology node may specify the smallest possible size (e.g., minimum size) that can be fabricated (e.g., size of a transistor, width of trace, gap with between two transistors). Different technology nodes may have different yield loss. Different technology nodes may have different costs. Technology nodes that produce components (e.g., trace, transistors) with fine details are more expensive and may have higher yield loss, than a technology node that produces components (e.g., trace, transistors) with details that are less fine. Thus, more advanced technology nodes may be more expensive and may have higher yield loss, than less advanced technology nodes. When all of the functions of a package are implemented in single integrated devices, the same technology node is used to fabricate the entire integrated device, even if some of the functions of the integrated devices do not need to be fabricated using that particular technology node. Thus, the integrated device is locked into one technology node. To optimize the cost of a package, some of the functions can be implemented in different integrated devices and/or chiplets, where different integrated devices and/or chiplets may be fabricated using different technology nodes to reduce overall costs. For example, functions that require the use of the most advance technology node may be implemented in an integrated device, and functions that can be implemented using a less advanced technology node can be implemented in another integrated device and/or one or more chiplets. One example, would be an integrated device, fabricated using a first technology node (e.g., most advanced technology node), that is configured to provide compute applications, and at least one chiplet, that is fabricated using a second technology node, that is configured to provide other functionalities, where the second technology node is not as costly as the first technology node, and where the second technology node fabricates components with minimum sizes that are greater than the minimum sizes of components fabricated using the first technology node. Examples of compute applications may include high performance computing and/or high performance processing, which may be achieved by fabricating and packing in as many transistors as possible in an integrated device, which is why an integrated device that is configured for compute applications may be fabricated using the most advanced technology node available, while other chiplets may be fabricated using less advanced technology nodes, since those chiplets may not require as many transistors to be fabricated in the chiplets. Thus, the combination of using different technology nodes (which may have different associated yield loss) for different integrated devices and/or chiplets, can reduce the overall cost of a package, compared to using a single integrated device to perform all the functions of the package.

Another advantage of splitting the functions into several integrated devices and/or chiplets, is that it allows improvements in the performance of the package without having to redesign every single integrated device and/or chiplet. For example, if a configuration of a package uses a first integrated device and a first chiplet, it may be possible to improve the performance of the package by changing the design of the first integrated device, while keeping the design of the first chiplet the same. Thus, the first chiplet could be reused with the improved and/or different configured first integrated device. This saves cost by not having to redesign the first chiplet, when packages with improved integrated devices are fabricated.

The package (e.g., 100, 300, 400) may be implemented in a radio frequency (RF) package. The RF package may be a radio frequency front end (RFFE) package. A package (e.g., 100, 300, 400) may be configured to provide Wireless Fidelity (WiFi) communication and/or cellular communication (e.g., 2G, 3G, 4G, 5G). The packages (e.g., 100, 300, 400) may be configured to support Global System for Mobile (GSM) Communications, Universal Mobile Telecommunications System (UMTS), and/or Long-Term Evolution (LTE). The packages (e.g., 100, 300, 400) may be configured to transmit and receive signals having different frequencies and/or communication protocols.

Having described various packages, a sequence for fabricating a package will now be described below.

Exemplary Sequence for Fabricating a Package Comprising Substrates with Post Interconnects

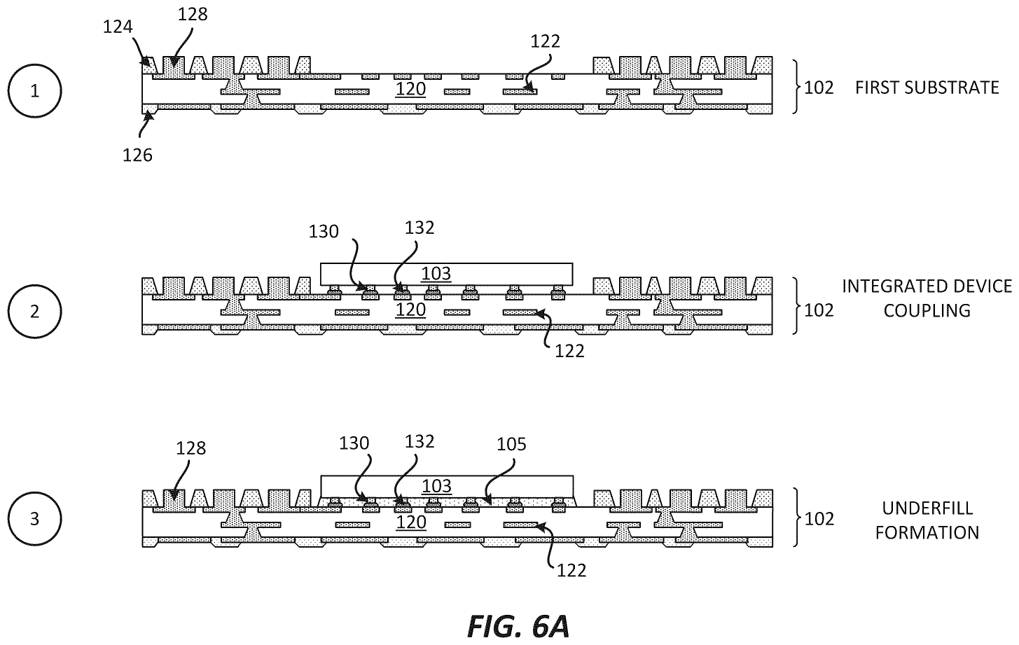

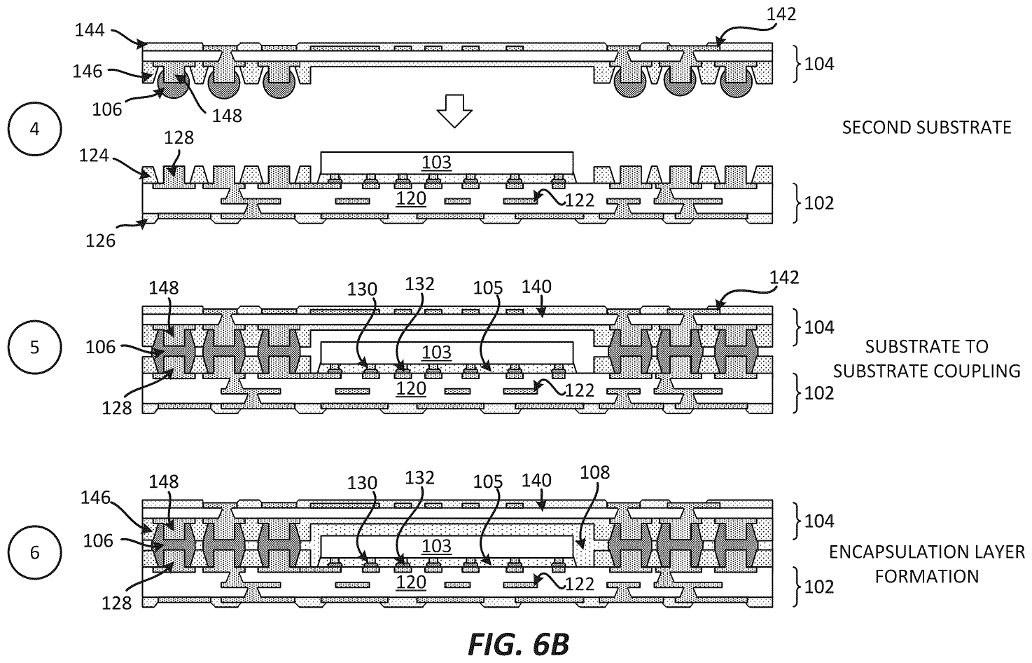

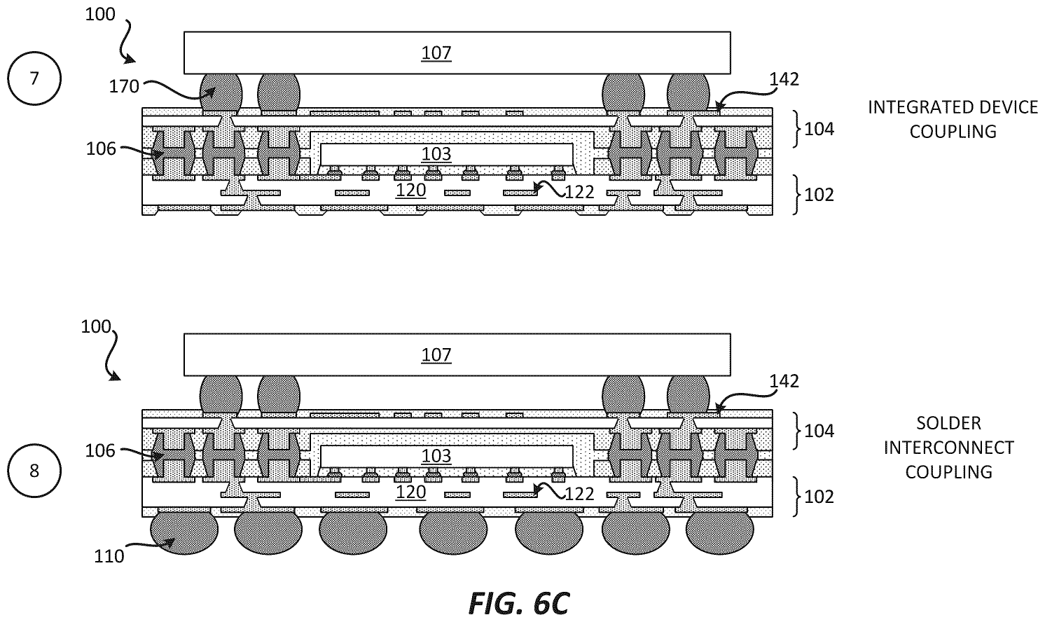

In some implementations, fabricating a package includes several processes. FIGS. 6A-6C illustrate an exemplary sequence for providing or fabricating a package. In some implementations, the sequence of FIGS. 6A-6C may be used to provide or fabricate the package 100. However, the process of FIGS. 6A-6C may be used to fabricate any of the packages (e.g., 300) described in the disclosure.

It should be noted that the sequence of FIGS. 6A-6C may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

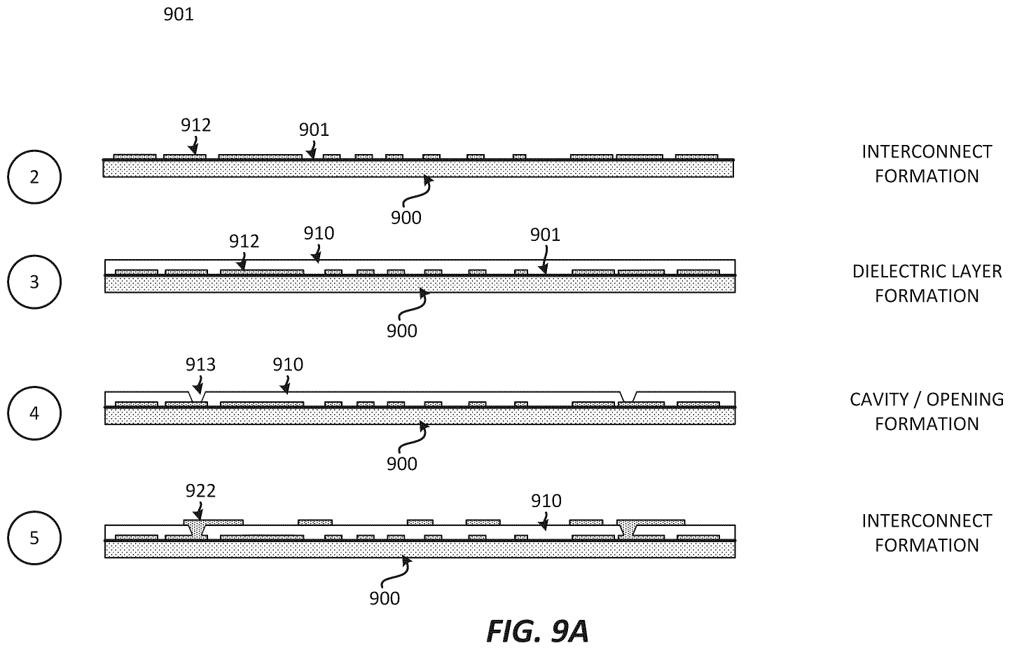

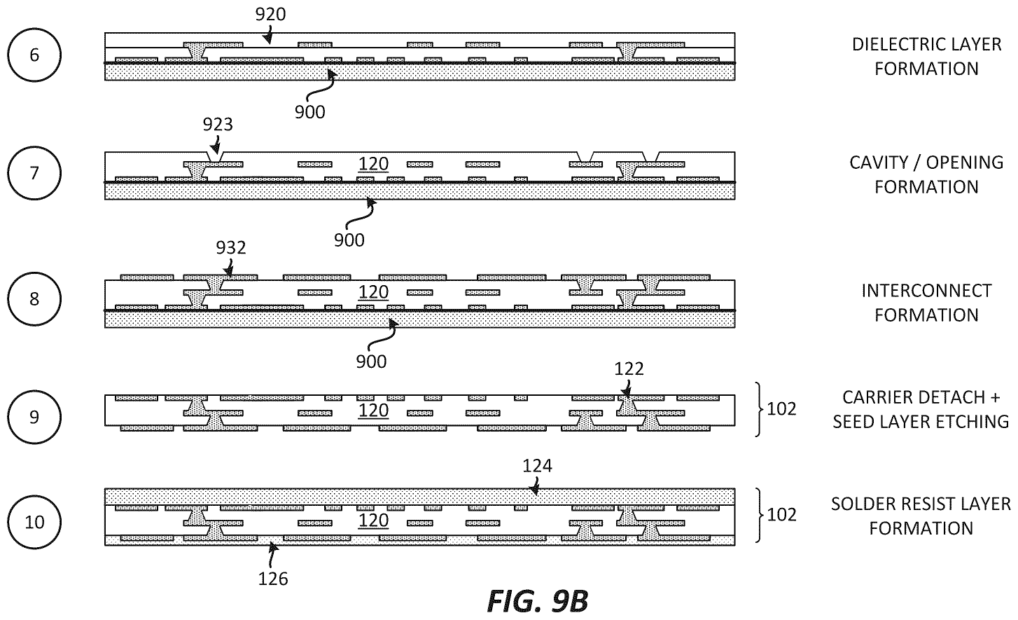

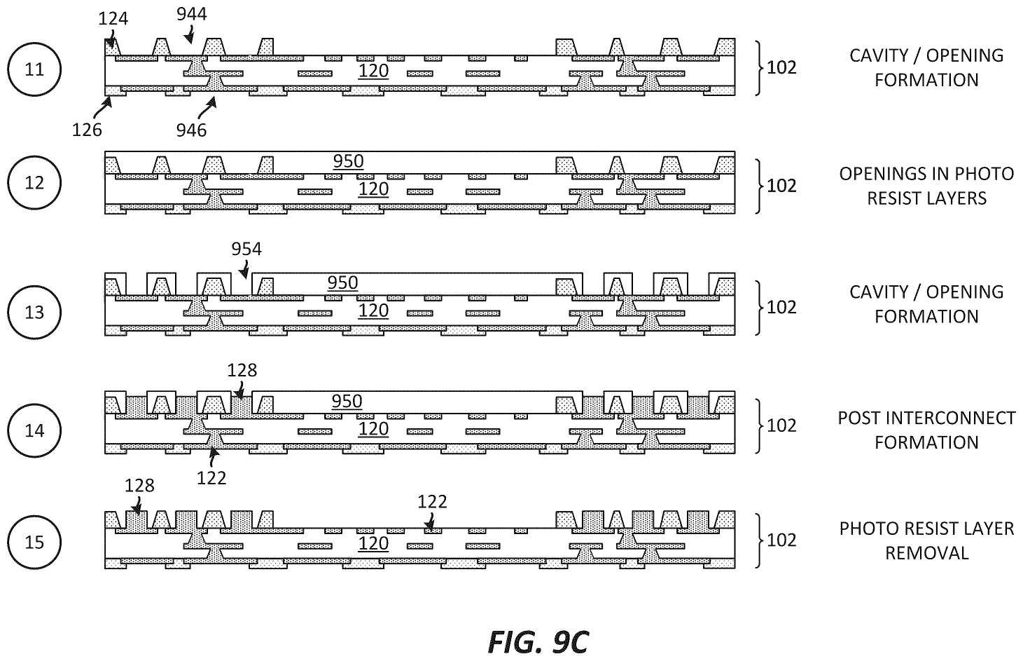

Stage 1, as shown in FIG. 6A, illustrates a state after a substrate 102 is provided. The substrate 102 may be a first substrate. The substrate 102 includes at least one dielectric layer 120, a plurality of interconnects 122, a solder resist layer 124 and a solder resist layer 126. The plurality of interconnects 122 may include a plurality of post interconnects 128. The substrate 102 may include a first surface (e.g., top surface) and a second surface (e.g., bottom surface). The substrate 102 may be fabricated using the method as described in FIGS. 9A-9C.

Stage 2 illustrates a state after an integrated device 103 is coupled to the first surface (e.g., top surface) of the substrate 102. The integrated device 103 may be coupled to the substrate 102 through the plurality of pillar interconnects 130 and the plurality of solder interconnects 132. In some implementations, the integrated device 103 may be coupled to the substrate 102 through the plurality of solder interconnects 132. A solder reflow process may be used to couple the integrated device 103 to the substrate 102.

Stage 3 illustrates a state after an underfill 105 is provided and/or formed between the integrated device 103 and the substrate 102. The underfill 105 may be dispensed underneath the integrated device 103.

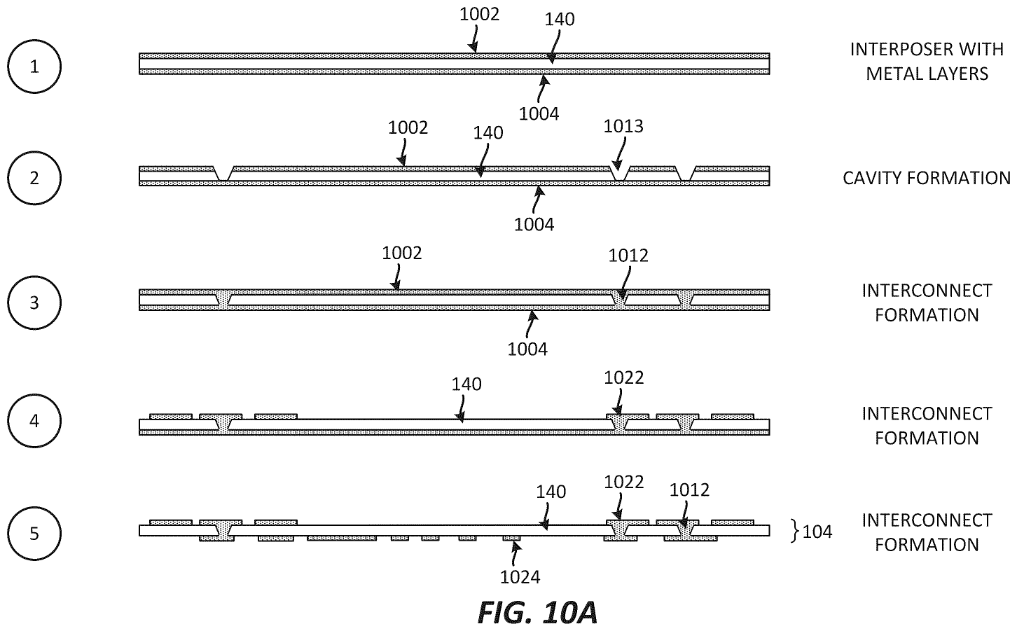

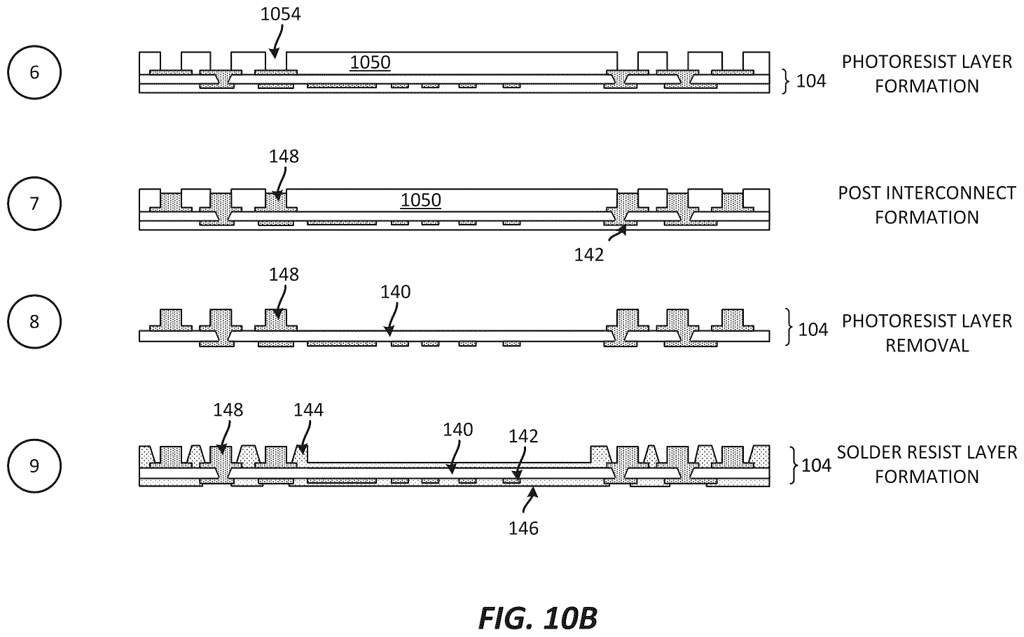

Stage 4, as shown in FIG. 6B, illustrates a state after a substrate 104 is provided. The substrate 104 may be a second substrate. The substrate 104 includes at least one dielectric layer 140, a plurality of interconnects 142, a solder resist layer 144 and a solder resist layer 146. The substrate 104 may include a first surface (e.g., top surface) and a second surface (e.g., bottom surface). The plurality of interconnects 142 may include a plurality of post interconnects 148. A plurality of solder interconnects 106 may be coupled to the substrate 104. The plurality of solder interconnects 106 may be coupled to the plurality of post interconnects 148. The substrate 104 may be fabricated using the method as described in FIGS. 10A-10B.

Stage 5 illustrates a state after the substrate 104 is coupled to the substrate 102 through the plurality of solder interconnects 106. A solder reflow process may be used to couple the substrate 104 to the substrate 102. The plurality of solder interconnects 106 may be coupled to the substrate 102 and the substrate 104. The plurality of solder interconnects 106 may be coupled to and touching the plurality of post interconnects 128 and the plurality of post interconnects 148. The substrate 104 is coupled to the substrate 102 such that the first integrated device 103 is located between the substrate 102 and the substrate 104.

Stage 6 illustrates a state after an encapsulation layer 108 is provided between the substrate 102 and the substrate 104. The encapsulation layer 108 may at least partially encapsulate the integrated device 103, the plurality of solder interconnects 106. The encapsulation layer 108 may be located between the substrate 102 and the substrate 104. The encapsulation layer 108 may be located between the back side of the integrated device 103 and the substrate 104. The encapsulation layer 108 may be located laterally to the plurality of solder interconnects 106. The encapsulation layer 108 may include a mold, a resin and/or an epoxy. The encapsulation layer 108 may be a means for encapsulation. The encapsulation layer 108 may be provided by using a compression and transfer molding process, a sheet molding process, or a liquid molding process.

Stage 7, as shown in FIG. 6C, illustrates a state after an integrated device 107 is coupled to the first surface (e.g., top surface) of the substrate 104. The integrated device 107 may be a second integrated device. The integrated device 107 may be coupled to the substrate 104 through the plurality of solder interconnects 170. A solder reflow process may be used to couple the second integrated device 107 to the substrate 104.

Stage 8 illustrates a state after a plurality of solder interconnects 110 are coupled to the second surface of the substrate 102. A solder reflow process may be used to couple the plurality of solder interconnects 110 to the substrate 102. Stage 8 may illustrate the package 100. The package 100 may be fabricated one at a time or may be fabricated together as part of one or more wafers and then singulated into individual packages.

Exemplary Flow Diagram of a Method for Fabricating a Package Comprising Substrates with Post Interconnects

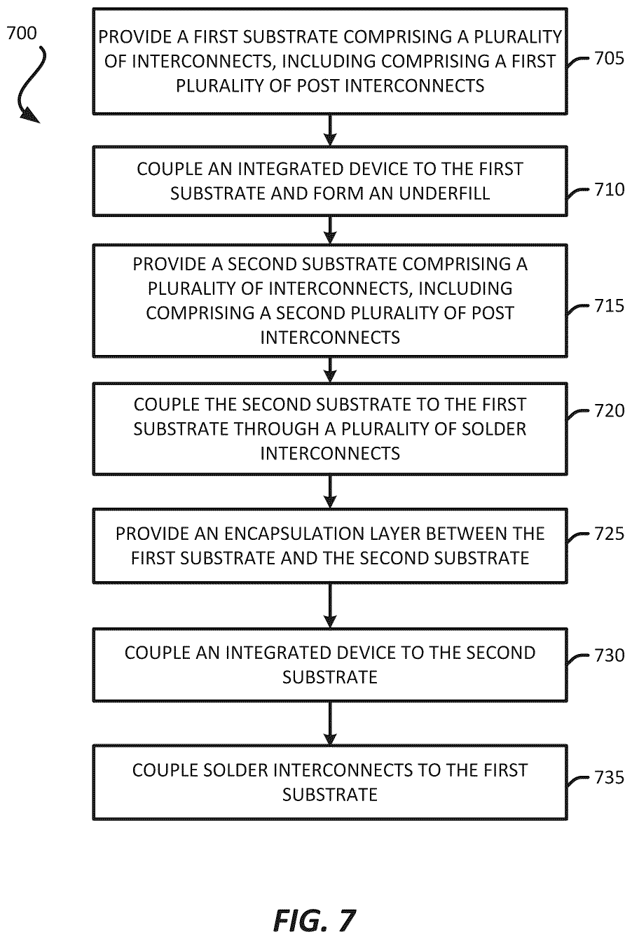

In some implementations, fabricating a package includes several processes. FIG. 7 illustrates an exemplary flow diagram of a method 700 for providing or fabricating a package. In some implementations, the method 700 of FIG. 7 may be used to provide or fabricate the package 100 described in the disclosure. However, the method 700 may be used to provide or fabricate any of the packages (e.g., 300) described in the disclosure.

It should be noted that the method 700 of FIG. 7 may combine one or more processes in order to simplify and/or clarify the method for providing or fabricating a package. In some implementations, the order of the processes may be changed or modified.

The method provides (at 705) a first substrate that includes a plurality of interconnects, including comprising a first plurality of post interconnects. Stage 1 of FIG. 6A, illustrates and describes an example of a state after a substrate 102 is provided. The substrate 102 may be a first substrate. The substrate 102 includes at least one dielectric layer 120, a plurality of interconnects 122, a solder resist layer 124 and a solder resist layer 126. The plurality of interconnects 122 may include a plurality of post interconnects 128. The substrate 102 may include a first surface (e.g., top surface) and a second surface (e.g., bottom surface). The substrate 102 may be fabricated using the method as described in FIGS. 9A-9C.

The method couples (at 710) a first integrated device to the first substrate and provides an underfill. Stage 2 of FIG. 6A, illustrates and describes an example of a state after an integrated device 103 is coupled to the first surface (e.g., top surface) of the substrate 102. The integrated device 103 may be coupled to the substrate 102 through the plurality of pillar interconnects 130 and the plurality of solder interconnects 132. In some implementations, the integrated device 103 may be coupled to the substrate 102 through the plurality of solder interconnects 132. A solder reflow process may be used to couple the integrated device 103 to the substrate 102.

Stage 3 of FIG. 6A, illustrates and describes an example of a state after an underfill 105 is provided and/or formed between the integrated device 103 and the substrate 102. The underfill 105 may be dispensed underneath the integrated device 103.

The method provides (at 715) a second substrate that includes a plurality of interconnects, including comprising a second plurality of post interconnects. Stage 4 of FIG. 6B, illustrates and describes an example of a state after a substrate 104 is provided. The substrate 104 may be a second substrate. The substrate 104 includes at least one dielectric layer 140, a plurality of interconnects 142, a solder resist layer 144 and a solder resist layer 146. The substrate 104 may include a first surface (e.g., top surface) and a second surface (e.g., bottom surface). The plurality of interconnects 142 may include a plurality of post interconnects 148. A plurality of solder interconnects 106 may be coupled to the substrate 104. The plurality of solder interconnects 106 may be coupled to the plurality of post interconnects 148. The substrate 104 may be fabricated using the method as described in FIGS. 10A-10B.

The method couples (at 720) the second substrate to the first substrate. Stage 5 of FIG. 6B, illustrates and describes an example of a state after the substrate 104 is coupled to the substrate 102 through the plurality of solder interconnects 106. A solder reflow process may be used to couple the substrate 104 to the substrate 102. The plurality of solder interconnects 106 may be coupled to the substrate 102 and the substrate 104. The plurality of solder interconnects 106 may be coupled to and touching the plurality of post interconnects 128 and the plurality of post interconnects 148. The substrate 104 is coupled to the substrate 102 such that the first integrated device 103 is located between the substrate 102 and the substrate 104.

The method provides (at 725) an encapsulation layer between the first substrate and the second substrate. Stage 6 of FIG. 6B, illustrates and describes an example of a state after an encapsulation layer 108 is provided between the substrate 102 and the substrate 104. The encapsulation layer 108 may at least partially encapsulate the integrated device 103, the plurality of solder interconnects 106. The encapsulation layer 108 may be located between the substrate 102 and the substrate 104. The encapsulation layer 108 may be located between the back side of the integrated device 103 and the substrate 104. The encapsulation layer 108 may be located laterally to the plurality of solder interconnects 106. The encapsulation layer 108 may include a mold, a resin and/or an epoxy. The encapsulation layer 108 may be a means for encapsulation. The encapsulation layer 108 may be provided by using a compression and transfer molding process, a sheet molding process, or a liquid molding process.

The method couples (730) a second integrated device to the second substrate. Stage 7 of FIG. 6C, illustrates and describes an example of a state after an integrated device 107 is coupled to the first surface (e.g., top surface) of the substrate 104. The integrated device 107 may be a second integrated device. The integrated device 107 may be coupled to the substrate 104 through the plurality of solder interconnects 170. A solder reflow process may be used to couple the second integrated device 107 to the substrate 104.

The method couples (at 735) a plurality of solder interconnects to the first substrate. Stage 8 of FIG. 6C, illustrates and describes an example of a state after a plurality of solder interconnects 110 are coupled to the second surface of the substrate 102. A solder reflow process may be used to couple the plurality of solder interconnects 110 to the substrate 102. Stage 8 may illustrate the package 100. The package 100 may be fabricated one at a time or may be fabricated together as part of one or more wafers and then singulated into individual packages.

### Exemplary Flow Diagram of a Method for Fabricating a Package Comprising Substrates Coupled Through Solder Interconnects

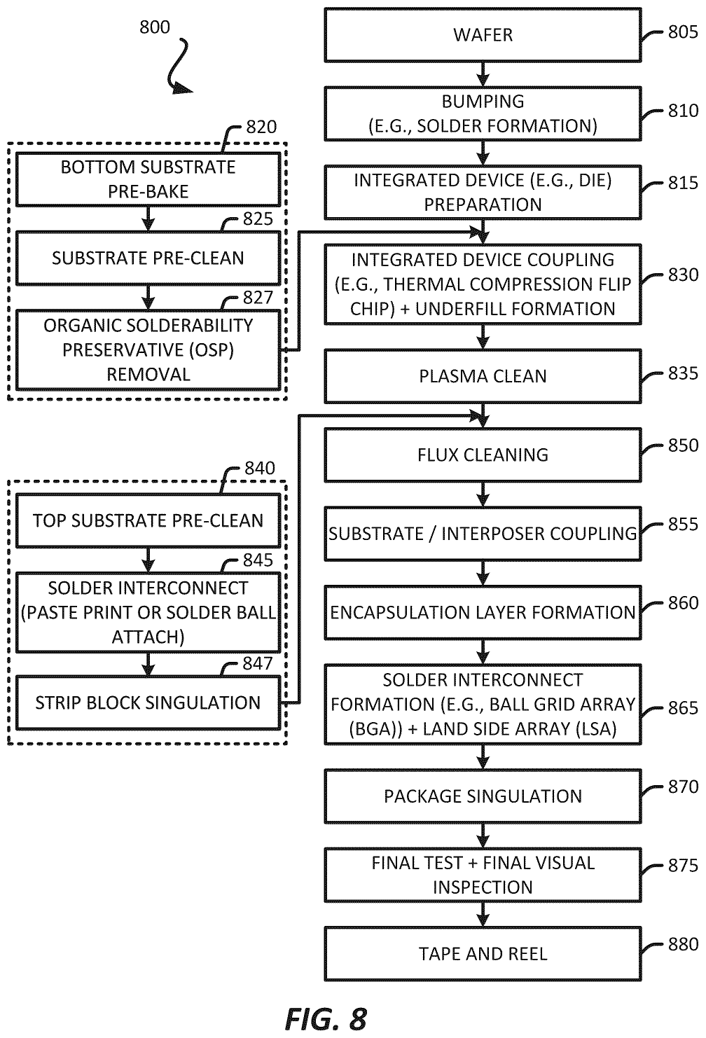

FIG. 8 illustrates an exemplary flow diagram of a method 800 for providing or fabricating a package. In some implementations, the method 800 of FIG. 8 may be used to provide or fabricate some or all of the package of FIG. 1 described in the disclosure. However, the method 800 may be used to provide or fabricate any of the packages described in the disclosure.

It should be noted that the method 800 of FIG. 8 may combine one or more processes in order to simplify and/or clarify the method for providing or fabricating a package. In some implementations, the order of the processes may be changed or modified.

The method provides (at 805) a wafer. The wafer may serve as a substrate on which integrated devices may be formed and/or coupled to. In some implementations, other substrates may be coupled to the wafer. The wafer may include silicon. The wafer may serve as a base on which components are built over.

The method forms (at 810) solder interconnects on the wafer. A solder reflow process may be used to form (e.g., couple) solder interconnects on the wafer.

The method prepares (at 815) one or more integrated devices (e.g., dies) for coupling. Preparing the integrated devices may include fabricating the integrated devices.

The method provides and prepares (at 820) a first substrate (e.g., substrate 102, bottom substrate) by pre-baking the first substrate. The first substrate may be pre-baked to remove moisture on the first substrate to avoid outgassing during a subsequent thermal compression flip chip coupling process. The method pre-cleans (at 825) the first substrate. The method removes (at 827) organic solderability preservative (OSP) on the first substrate.

Once the first substrate is provided and prepared, the first substrate may be coupled to the wafer through the solder interconnects that are formed on the wafer.

The integrated device(s) is/are coupled (at 830) to the first substrate. For example, the integrated device 103 may be coupled to the substrate 102 through a thermal compression flip chip process. An underfill may be provided between the integrated device and the substrate. Stage 2 of FIG. 6A illustrates and describes an example of an integrated device that is coupled to a substrate. Stage 3 of FIG. 6A illustrates and describes an example of an underfill that is provided between the integrated device and the substrate.

The method performs (at 835) a plasma clean of the first substrate. The plasma clean may remove contamination on the surface of the substrate.

The method pre-cleans (at 840) a second substrate (e.g., substrate 104, top substrate). Stage 4 of FIG. 6B illustrates and describes an example of a second substrate that is provided. The method forms (at 845) solder interconnects on the second substrate. The solder interconnects (e.g., 106) may be coupled to the second substrate 104 through a paste printing process or through solder ball attach process. A solder reflow process may be used to couple the ball interconnects to the second substrate. The method performs (at 847) strip block singulation of the second substrate. This may be done, when several substrates are fabricated at the same time and then subsequently singulated.

The method performs (at 850) a flux cleaning of one or more substrates. Flux cleaning may remove oxides from metal of the substrate. The flux cleaning may be performed on the first substrate and/or the second substrate.

The method couples (at 855) the second substrate (e.g., 104) to the first substrate (e.g., 102) through the solder interconnects. A solder reflow process may be used to couple the second substrate to the first substrate. Stage 5 of FIG. 6B illustrates and describes an example of coupling a substrate to another substrate.

The method provides (at 860) an encapsulation layer (e.g., 108) between the first substrate and the second substrate. Stage 6 of FIG. 6B illustrates and describes an example providing an encapsulation layer between substrates.

The method forms (at 865) solder interconnects or land side array (LSA) on the first substrate. A solder reflow process may be used to form the solder interconnects. The solder interconnects may be a ball grid array (BGA).

The method singulates (at 870) the packages into individual packages. This may occur when several packages are fabricated at the same time. Singulating the package may include singulating the wafer that includes the first substrates, the integrated device(s), and the second substrates. A mechanical process (e.g., saw) or a laser may be used to singulate the packages.

The method performs (at 875) a final test and final visual inspection of the package. This may include testing whether the package works properly by attaching probes to the package to determine whether the package works as intended. Visual inspection may include visually inspecting to see whether the package has any defects.

The method performs (at 880) tape and reel of the packages. This may include packaging the singulated packages together with tape so that the package can be properly shipped.

It is noted that additional processes may be performed on the packages, including coupling other components, such as passive components and/or integrated devices to the packages. FIG. 8 illustrates an example of how packages may be fabricated. FIG. 8 is not intended to illustrate the only way that a package may be fabricated.

### Exemplary Sequence for Fabricating a Substrate

In some implementations, fabricating a substrate includes several processes. FIGS. 9A-9C illustrate an exemplary sequence for providing or fabricating a substrate. In some implementations, the sequence of FIGS. 9A-9C may be used to provide or fabricate the substrate 102. However, the process of FIGS. 9A-9C may be used to fabricate any of the substrates described in the disclosure.

It should be noted that the sequence of FIGS. 9A-9C may combine one or more stages in order to simplify and/or clarify the sequence for providing or fabricating a substrate. In some implementations, the order of the processes may be changed or modified. In some implementations, one or more of processes may be replaced or substituted without departing from the scope of the disclosure.

Stage 1, as shown in FIG. 9A, illustrates a state after a carrier 900 is provided. A seed layer 901 may be located over the carrier 900.

Stage 2 illustrates a state after a plurality of interconnects 912 are formed. The interconnects 912 may be located over the seed layer 901. A plating process and etching process may be used to form the plurality of interconnects 912. The interconnects 912 may represent at least some of the interconnects from the plurality of interconnects 122.

Stage 3 illustrates a state after a dielectric layer 910 is formed over the carrier 900, the seed layer 901 and the plurality of interconnects 912. A deposition and/or lamination process may be used to form the dielectric layer 910. The dielectric layer 910 may include prepreg and/or polyimide. The dielectric layer 910 may include a photo-imageable dielectric. However, different implementations may use different materials for the dielectric layer.

Stage 4 illustrates a state after a plurality of cavities 913 is formed in the dielectric layer 910. The plurality of cavities 913 may be formed using an etching process (e.g., photo etching process) or laser process.

Stage 5 illustrates a state after interconnects 922 are formed in and over the dielectric layer 910, including in and over the plurality of cavities 913. For example, a via, pad and/or traces may be formed. A plating process may be used to form the interconnects.

Stage 6, as shown in FIG. 9B, illustrates a state after a dielectric layer 920 is formed over the dielectric layer 910 and the plurality of interconnects 922. A deposition and/or lamination process may be used to form the dielectric layer 920. The dielectric layer 920 may include prepreg and/or polyimide. The dielectric layer 920 may include a photo-imageable dielectric. However, different implementations may use different materials for the dielectric layer.

Stage 7, illustrates a state after a plurality of cavities 923 is formed in the dielectric layer 120. The dielectric layer 120 may represent the dielectric layer 910 and/or the dielectric layer 920. The plurality of cavities 923 may be formed using an etching process (e.g., photo etching process) or laser process.

Stage 8 illustrates a state after interconnects 932 are formed in and over the dielectric layer 120, including in and over the plurality of cavities 923. For example, a via, pad and/or traces may be formed. A plating process may be used to form the interconnects.

Stage 9 illustrates a state after the carrier 900 is decoupled (e.g., detached, removed, grinded out) from at least one dielectric layer 120 and the seed layer 901, portions of the seed layer 901 are removed (e.g., etched out), leaving the substrate 102 that includes at least one dielectric layer 120 and the plurality of interconnects 122. The plurality of interconnects 122 may represent the plurality of interconnects 912, the plurality of interconnects 922 and/or the plurality of interconnects 932.

Stage 10 illustrates a state after the solder resist layer 124 is formed over the first surface of the substrate 102, and after the solder resist layer 126 is formed over the second surface of the substrate 102. A deposition process and/or lamination process may be used to form the solder resist layer 124 and/or the solder resist layer 126.

Stage 11, as shown in FIG. 9C, illustrates a state after openings 944 are formed in the solder resist layer 124 and/or openings 946 are formed in the solder resist layer 126. An etching process may be used to form the openings 944 and/or the openings 946.

Stage 12 illustrates a state after a photo resist layer 950 is formed over a surface of the substrate 102. The photo resist layer 950 may be deposited over the solder resist layer 124. A deposition process and/or a lamination process may be used to form the photo resist layer 950.

Stage 13 illustrates a state after openings 954 are formed in the photo resist layer 950. An etching process may be used to form the openings 954 in the photo resist layer 950.

Stage 14 illustrates a state after a plurality of post interconnects 128 are formed in the openings 954 of the photo resist layer 950. The plurality of post interconnects 128 may be coupled to the plurality of interconnects 122. A plating process may be used to form the plurality of post interconnects 128.

Stage 15 illustrates a state after the photo resist layer 950 is removed, leaving the substrate 102 that includes the at least one dielectric layer 120, the plurality of interconnects 122, the plurality of post interconnects 128, the solder resist layer 124 and the solder resist layer 126.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Sequence for Fabricating a Substrate

In some implementations, fabricating a substrate includes several processes. FIGS. 10A-10B illustrate an exemplary sequence for providing or fabricating a substrate. In some implementations, the sequence of FIGS. 10A-10B may be used to provide or fabricate the substrate 104. However, the process of FIGS. 10A-10B may be used to fabricate any of the substrates described in the disclosure.

It should be noted that the sequence of FIGS. 10A-10B may combine one or more stages in order to simplify and/or clarify the sequence for providing or fabricating a substrate. In some implementations, the order of the processes may be changed or modified. In some implementations, one or more of processes may be replaced or substituted without departing from the scope of the disclosure.

Stage 1, as shown in FIG. 9A, illustrates a state after an interposer is provided. The interposer includes a dielectric layer 140, a metal layer 1002 and a metal layer 1004. The metal layer 1002 is formed on and coupled to a first surface of the dielectric layer 140. The metal layer 1004 is formed on and coupled to a second surface of the dielectric layer 140.

Stage 2 illustrates a state after a plurality of cavities 1013 are formed in the metal layer 1002 and the dielectric layer 140. An etching process may be used to form the plurality of cavities 1013.

Stage 3 illustrates a state after a plurality of interconnects 1012 are formed. The interconnects 1012 may be located in the plurality of cavities 1013. The plurality of interconnects 1012 may be coupled to the metal layer 1002 and the metal layer 1004. A plating process may be used to form the plurality of interconnects 1012.

Stage 4 illustrates a state after a plurality of interconnects 1022 are formed. The plurality of interconnects 1022 may be formed from the metal layer 1002. An etching process may be used to form the plurality of interconnects 1022. The plurality of interconnects 1022 may be formed on a first surface of the dielectric layer 140. The plurality of interconnects 1022 may be coupled to the plurality of interconnects 1012.

Stage 5 illustrates a state after a plurality of interconnects 1024 are formed. The plurality of interconnects 1024 may be formed from the metal layer 1004. An etching process may be used to form the plurality of interconnects 1024. The plurality of interconnects 1024 may be formed on a second surface of the dielectric layer 140. The plurality of interconnects 1024 may be coupled to the plurality of interconnects 1012.

Stage 6 illustrates a state after a photo resist layer 1050 is formed over a first surface of the substrate 104. The photo resist layer 1050 may be deposited over the plurality of interconnects 1022. A deposition process and/or a lamination process may be used to form the photo resist layer 1050. Stage 6 also illustrates a state after openings 1054 are formed in the photo resist layer 1050. An etching process may be used to form the openings 1054 in the photo resist layer 1050.

Stage 7 illustrates a state after a plurality of post interconnects 148 are formed in the openings 1054 of the photo resist layer 1050. The plurality of post interconnects 148 may be coupled to the plurality of interconnects 142. A plating process may be used to form the plurality of post interconnects 148. The plurality of interconnects 142 may represent the plurality of interconnects 1012, the plurality of interconnects 1022 and/or the plurality of interconnects 1024.

Stage 8 illustrates a state after the photo resist layer 1050 is removed, leaving the substrate 104 that includes the at least one dielectric layer 140, the plurality of interconnects 142, and the plurality of post interconnects 148.

Stage 9 illustrate a state a solder resist layer 144 and a solder resist layer 146 are formed and coupled to the substrate 104. Stage 9 illustrates a substrate 104 that includes at least one dielectric layer 140, a plurality of interconnects 142, a plurality of post interconnects 148, a solder resist layer 144 and a solder resist layer 146.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Flow Diagram of a Method for Fabricating a Substrate

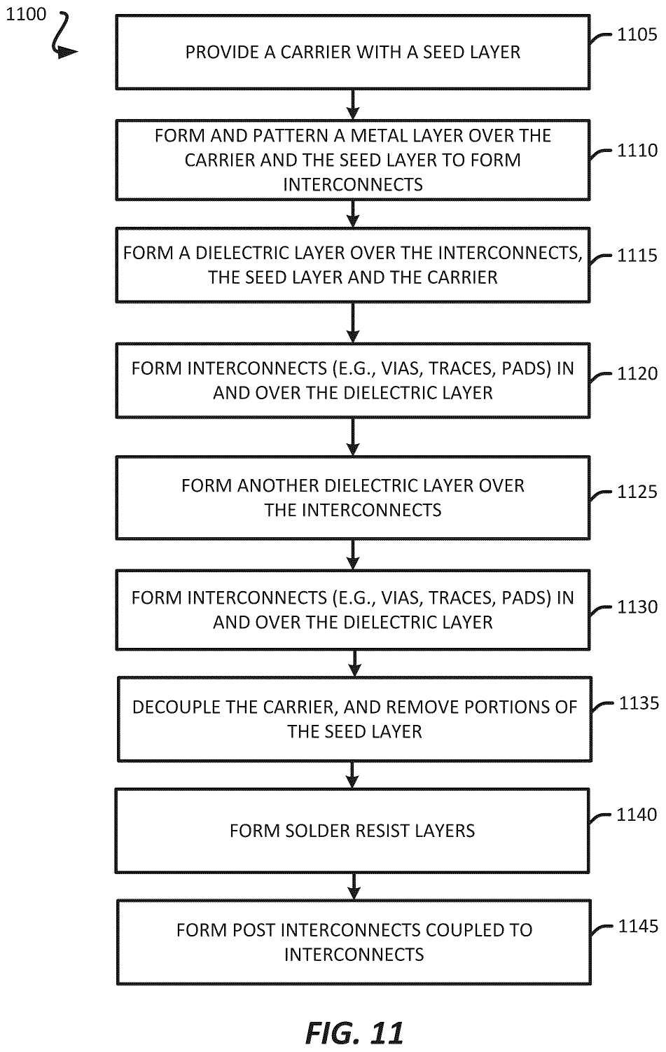

In some implementations, fabricating a substrate includes several processes. FIG. 11 illustrates an exemplary flow diagram of a method 1100 for providing or fabricating a substrate. In some implementations, the method 1100 of FIG. 11 may be used to provide or fabricate the substrate(s) of the disclosure. For example, the method 1100 of FIG. 11 may be used to fabricate the substrate 102.

It should be noted that the method 1100 of FIG. 11 may combine one or more processes in order to simplify and/or clarify the method for providing or fabricating a substrate. In some implementations, the order of the processes may be changed or modified.

The method provides (at 1105) a carrier with a seed layer. Stage 1 of FIG. 9A, illustrates and describes an example of a state after a carrier 900 is provided. A seed layer 901 may be located over the carrier 900.

The method forms and patterns (at 1110) a plurality of interconnects. Stage 2 of FIG. 9A, illustrates and describes an example of a state after a plurality of interconnects 912 are formed. The interconnects 912 may be located over the seed layer 901. A plating process and etching process may be used to form the plurality of interconnects 912. The interconnects 912 may represent at least some of the interconnects from the plurality of interconnects 122.

The method forms (at 1115) a dielectric layer. Stage 3 of FIG. 9A, illustrates and describes an example of a state after a dielectric layer 910 is formed over the carrier 900, the seed layer 901 and the plurality of interconnects 912. A deposition and/or lamination process may be used to form the dielectric layer 910. The dielectric layer 910 may include prepreg and/or polyimide. The dielectric layer 910 may include a photo-imageable dielectric. However, different implementations may use different materials for the dielectric layer.

The method forms (at 1120) a plurality of interconnects. Forming a plurality of interconnects may including forming a plurality of cavities in a dielectric layer and a performing a plating process. Stage 4 of FIG. 9A, illustrates and describes an example of a state after a plurality of cavities 913 is formed in the dielectric layer 910. The plurality of cavities 913 may be formed using an etching process (e.g., photo etching process) or laser process.

Stage 5 of FIG. 9A, illustrates and describes an example of a state after interconnects 922 are formed in and over the dielectric layer 910, including in and over the plurality of cavities 913. For example, a via, pad and/or traces may be formed. A plating process may be used to form the interconnects.

The method forms (at 1125) another dielectric layer. Stage 6 of FIG. 9B, illustrates and describes an example of a state after a dielectric layer 920 is formed over the dielectric layer 910 and the plurality of interconnects 922. A deposition and/or lamination process may be used to form the dielectric layer 920. The dielectric layer 920 may include prepreg and/or polyimide. The dielectric layer 920 may include a photo-imageable dielectric. However, different implementations may use different materials for the dielectric layer.

The method forms (at 1130) a plurality of interconnects. Forming a plurality of interconnects may including forming a plurality of cavities in a dielectric layer and a performing a plating process. Stage 7 of FIG. 9B, illustrates and describes an example of a state after a plurality of cavities 923 is formed in the dielectric layer 120. The dielectric layer 120 may represent the dielectric layer 910 and/or the dielectric layer 920. The plurality of cavities 923 may be formed using an etching process (e.g., photo etching process) or laser process.

Stage 8 of FIG. 9B, illustrates and describes an example of a state after interconnects 932 are formed in and over the dielectric layer 120, including in and over the plurality of cavities 923. For example, a via, pad and/or traces may be formed. A plating process may be used to form the interconnects.

The method decouples (at 1135) a carrier. Stage 9 of FIG. 9B, illustrates and describes an example of a state after the carrier 900 is decoupled (e.g., detached, removed, grinded out) from at least one dielectric layer 120 and the seed layer 901, portions of the seed layer 901 are removed (e.g., etched out), leaving the substrate 102 that includes at least one dielectric layer 120 and the plurality of interconnects 122. The plurality of interconnects 122 may represent the plurality of interconnects 912, the plurality of interconnects 922 and/or the plurality of interconnects 932.

The method forms (at 1140) solder resist layers. Stage 10 of FIG. 9B, illustrates and describes an example of a state after the solder resist layer 124 is formed over the first surface of the substrate 102, and after the solder resist layer 126 is formed over the second surface of the substrate 102. A deposition process and/or lamination process may be used to form the solder resist layer 124 and/or the solder resist layer 126.

Stage 11 of FIG. 9C, illustrates and describes an example of a state after openings 944 are formed in the solder resist layer 124 and/or openings 946 are formed in the solder resist layer 126. An etching process may be used to form the openings 944 and/or the openings 946.

The method forms (at 1145) a plurality of post interconnects. Forming the plurality of interconnects may include forming a photo resist layer, forming an openings in the photo resist layer, and performing a plating process.

Stage 12 of FIG. 9C, illustrates and describes an example of a state after a photo resist layer 950 is formed over a surface of the substrate 102. The photo resist layer 950 may be deposited over the solder resist layer 124. A deposition process and/or a lamination process may be used to form the photo resist layer 950.

Stage 13 of FIG. 9C, illustrates and describes an example of a state after openings 954 are formed in the photo resist layer 950. An etching process may be used to form the openings 954 in the photo resist layer 950.

Stage 14 of FIG. 9C, illustrates and describes an example of a state after a plurality of post interconnects 128 are formed in the openings 954 of the photo resist layer 950. The plurality of post interconnects 128 may be coupled to the plurality of interconnects 122. A plating process may be used to form the plurality of post interconnects 128.

Stage 15 of FIG. 9C, illustrates and describes an example of a state after the photo resist layer 950 is removed, leaving the substrate 102 that includes the at least one dielectric layer 120, the plurality of interconnects 122, the plurality of post interconnects 128, the solder resist layer 124 and the solder resist layer 126.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Electronic Devices

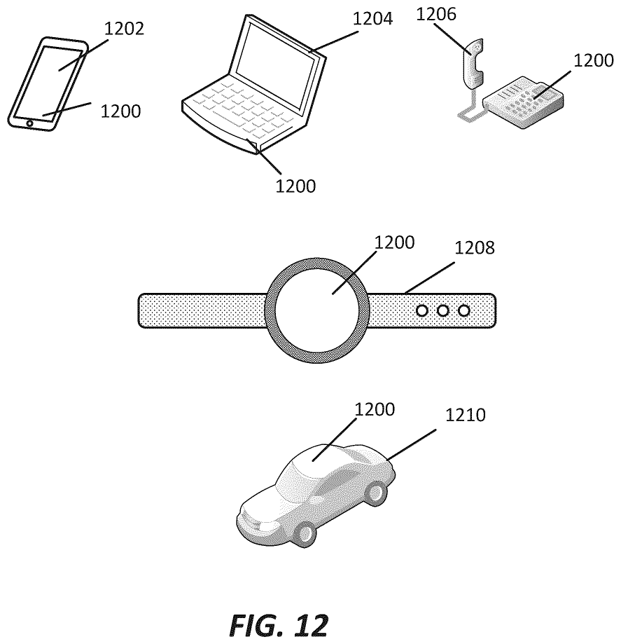

FIG. 12 illustrates various electronic devices that may be integrated with any of the aforementioned device, integrated device, integrated circuit (IC) package, integrated circuit (IC) device, semiconductor device, integrated circuit, die, interposer, package, package-on-package (PoP), System in Package (SiP), or System on Chip (SoC). For example, a mobile phone device 1202, a laptop computer device 1204, a fixed location terminal device 1206, a wearable device 1208, or automotive vehicle 1210 may include a device 1200 as described herein. The device 1200 may be, for example, any of the devices and/or integrated circuit (IC) packages described herein. The devices 1202, 1204, 1206 and 1208 and the vehicle 1210 illustrated in FIG. 12 are merely exemplary. Other electronic devices may also feature the device 1200 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-5, 6A-6C, 7-8, 9A-9C, 10A-10B and 11-12 may be rearranged and/or combined into a single component, process, feature or function or embodied in several components, processes, or functions. Additional elements, components, processes, and/or functions may also be added without departing from the disclosure. It should also be noted FIGS. 1-5, 6A-6C, 7-8, 9A-9C, 10A-10B and 11-12 and its corresponding description in the present disclosure is not limited to dies and/or ICs. In some implementations, FIGS. 1-5, 6A-6C, 7-8, 9A-9C, 10A-10B and 11-12 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1.

In some implementations, an interconnect is an element or component of a device or package that allows or facilitates an electrical connection between two points, elements and/or components. In some implementations, an interconnect may include a trace (e.g., trace interconnect), a via (e.g., via interconnect), a pad (e.g., pad interconnect), a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the invention.

Aspect 1: A package comprising a first substrate comprising: at least one first dielectric layer; and a first plurality of interconnects, wherein the first plurality of interconnects include a first plurality of post interconnects; a first integrated device coupled to the first substrate; a second substrate coupled to the first substrate through at least a plurality of solder interconnects, wherein the second substrate comprises: at least one second dielectric layer; and a second plurality of interconnects, wherein the second plurality of interconnects include a second plurality of post interconnects; and an encapsulation layer located between the first substrate and the second substrate.

Aspect 2: The package of aspect 1, wherein the encapsulation layer touches the first substrate, the second substrate, the plurality of solder interconnects and the first integrated device.

Aspect 3: The package of aspects 1 through 2, wherein the encapsulation layer is located between the second substrate and the first integrated device.

Aspect 4: The package of aspect 3, wherein the encapsulation layer touches the second substrate and a back side of the first integrated device.

Aspect 5: The package of aspects 1 through 4, wherein the plurality of solder interconnects are coupled to the first plurality of post interconnects and the second plurality of post interconnects.

Aspect 6: The package of aspect 5, wherein the encapsulation layer touches the plurality of solder interconnects.

Aspect 7: The package of aspect 5, wherein the encapsulation layer further touches the first integrated device.

Aspect 8: The package of aspects 1 through 7, wherein the first integrated device is coupled to the first substrate through a second plurality of solder interconnects.

Aspect 9: The package of aspects 1 through 7, wherein the first integrated device is coupled to the first substrate through a plurality of pillar interconnects and a second plurality of solder interconnects.

Aspect 10: The package of aspects 1 through 9, further comprising a second integrated device coupled to the second substrate through a second plurality of solder interconnects.

Aspect 11: The package of aspect 10, wherein an electrical path between the first integrated device and the second integrated device comprises an interconnect from the first plurality of interconnects, a post interconnect from the first plurality of post interconnects, a solder interconnect from the plurality of solder interconnects, a post interconnect from the second plurality of post interconnects, an interconnect from the second plurality of post interconnects, and a solder interconnect from the second plurality of solder interconnects.

Aspect 12: The package of aspect 11, further comprising a third substrate coupled to the second substrate through a second plurality of solder interconnects, wherein the third substrate comprises: at least one third dielectric layer; and a third plurality of interconnects; and a second integrated device coupled to the third substrate through a third plurality of solder interconnects.

Aspect 13: The package of aspect 12, wherein an electrical path between the first integrated device and the second integrated device comprises an interconnect from the first plurality of interconnects, a post interconnect from the first plurality of post interconnects, a solder interconnect from the plurality of solder interconnects, a post interconnect from the second plurality of post interconnects, an interconnect from the second plurality of post interconnects, a solder interconnect from the second plurality of solder interconnects, an interconnect from the third plurality of interconnects, and a solder interconnect from the third plurality of solder interconnects.

Aspect 14: A method for fabricating a package. The method provides a first substrate comprising: at least one first dielectric layer; and a first plurality of interconnects, wherein the first plurality of interconnects include a first plurality of post interconnects. The method couples a first integrated device to the first substrate. The method couples a second substrate to the first substrate through at least a plurality of solder interconnects, wherein the second substrate comprises: at least one second dielectric layer; and a second plurality of interconnects, wherein the second plurality of interconnects include a second plurality of post interconnects. The method forms an encapsulation layer located between the first substrate and the second substrate.

Aspect 15: The method of aspect 14, wherein the encapsulation layer touches the first substrate, the second substrate, the plurality of solder interconnects and the first integrated device.

Aspect 16: The method of aspects 14 through 15, wherein the encapsulation layer is located between the second substrate and the first integrated device.

Aspect 17: The method of aspect 16, wherein the encapsulation layer touches the second substrate and a back side of the first integrated device.

Aspect 18: The method of aspects 14 through 17, wherein the plurality of solder interconnects are coupled to the first plurality of post interconnects and the second plurality of post interconnects.

Aspect 19: The method of aspect 18, wherein the encapsulation layer touches the plurality of solder interconnects.

Aspect 20: The method of aspect 18, wherein the encapsulation layer further touches the first integrated device.

Aspect 21: The package of aspects 1 through 13, wherein the package is implemented in a device that is selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A package comprising:
a first substrate comprising:
at least one first dielectric layer; and
a first plurality of interconnects, wherein the first plurality of interconnects include a first plurality of post interconnects;
a first integrated device coupled to the first substrate;
a second substrate coupled to the first substrate through at least a plurality of solder interconnects, wherein the second substrate comprises:
at least one second dielectric layer; and
a second plurality of interconnects, wherein the second plurality of interconnects include a second plurality of post interconnects; and
an encapsulation layer located between the first substrate and the second substrate.

2. The package of claim 1, wherein the encapsulation layer touches the first substrate, the second substrate, the plurality of solder interconnects and the first integrated device.

3. The package of claim 1, wherein the encapsulation layer is located between the second substrate and the first integrated device.

4. The package of claim 3, wherein the encapsulation layer touches the second substrate and a back side of the first integrated device.

5. The package of claim 1, wherein the plurality of solder interconnects are coupled to the first plurality of post interconnects and the second plurality of post interconnects.

6. The package of claim 5, wherein the encapsulation layer touches the plurality of solder interconnects.

7. The package of claim 5, wherein the encapsulation layer further touches the first integrated device.

8. The package of claim 1, wherein the first integrated device is coupled to the first substrate through a second plurality of solder interconnects.

9. The package of claim 1, wherein the first integrated device is coupled to the first substrate through a plurality of pillar interconnects and a second plurality of solder interconnects.

10. The package of claim 1, further comprising a second integrated device coupled to the second substrate through a second plurality of solder interconnects.

11. The package of claim 10, wherein an electrical path between the first integrated device and the second integrated device comprises an interconnect from the first plurality of interconnects, a post interconnect from the first plurality of post interconnects, a solder interconnect from the plurality of solder interconnects, a post interconnect from the second plurality of post interconnects, an interconnect from the second plurality of post interconnects, and a solder interconnect from the second plurality of solder interconnects.

12. The package of claim 11, further comprising:
a third substrate coupled to the second substrate through a second plurality of solder interconnects, wherein the third substrate comprises:
at least one third dielectric layer; and
a third plurality of interconnects; and
a second integrated device coupled to the third substrate through a third plurality of solder interconnects.

13. The package of claim 12, wherein an electrical path between the first integrated device and the second integrated device comprises an interconnect from the first plurality of interconnects, a post interconnect from the first plurality of post interconnects, a solder interconnect from the plurality of solder interconnects, a post interconnect from the second plurality of post interconnects, an interconnect from the second plurality of post interconnects, a solder interconnect from the second plurality of solder interconnects, an interconnect from the third plurality of interconnects, and a solder interconnect from the third plurality of solder interconnects.

14. A method for fabricating a package, comprising:
providing a first substrate comprising:
at least one first dielectric layer; and
a first plurality of interconnects, wherein the first plurality of interconnects include a first plurality of post interconnects;
coupling a first integrated device to the first substrate;
coupling a second substrate to the first substrate through at least a plurality of solder interconnects, wherein the second substrate comprises:
at least one second dielectric layer; and
a second plurality of interconnects, wherein the second plurality of interconnects include a second plurality of post interconnects; and
forming an encapsulation layer located between the first substrate and the second substrate.

15. The method of claim 14, wherein the encapsulation layer touches the first substrate, the second substrate, the plurality of solder interconnects and the first integrated device.

16. The method of claim 14, wherein the encapsulation layer is located between the second substrate and the first integrated device.

17. The method of claim 16, wherein the encapsulation layer touches the second substrate and a back side of the first integrated device.

18. The method of claim 14, wherein the plurality of solder interconnects are coupled to the first plurality of post interconnects and the second plurality of post interconnects.

19. The method of claim 18, wherein the encapsulation layer touches the plurality of solder interconnects.

20. The method of claim 18, wherein the encapsulation layer further touches the first integrated device.
